(19) United States
(12) Patent Application Publication
(10) Pub. No.: US 2007/0147114 A1
(43) Pub. Date: Jun. 28, 2007

(54) SEMICONDUCTOR MEMORY SYSTEM

(75) Inventor: Ken Takeuchi, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/616,534

(22) Filed: Dec. 27, 2006

(30) Foreign Application Priority Data
Dec. 28, 2005 (JP) 2005-377850

(51) Int. Cl. G11C 11/34; G11C 16/04

(52) U.S. Cl. 365/185.03

(57) ABSTRACT

A semiconductor memory system includes: a non-volatile semiconductor memory device; and a memory controller configured to execute operation control of the non-volatile semiconductor memory device, wherein a sequencer contained in control logic for the non-volatile semiconductor memory device is composed of software developed in the memory controller.

### CROSS-REFERENCE TO RELATED APPLICATION

This application is based on and claims the benefit of priority from the prior Japanese Patent Application No. 2005-377850, filed on Dec. 28, 2005, the entire contents of which are incorporated herein by reference.

### BACKGROUND OF THE INVENTION

1. Field of the Invention

This invention relates to a semiconductor memory system including a non-volatile semiconductor memory and a memory controller for controlling it.

2. Description of the Related Art

A NAND-type flash memory is known as one of electrically rewritable and non-volatile semiconductor memories (EEPROMs). The NAND-type flash memory has a feature that the unit cell area is smaller than NOR-type one, therefore it is easy to increase the capacity. With a page buffer which is able to store one page data, it becomes possible to perform data read and write by a page between the cell array and the page buffer. Performing serial data transfer by a Byte (or two Bytes) between the page buffer and the outside of the chip, it becomes possible to perform data read or write at a substantially high rate.

In the conventional NAND-type flash memory to internally control read, write and erase in the chip, a hardware logic circuit is formed therein as an internal controller. However, in accordance with increasing the storage capacity and making data multi-level, the control logic of the internal controller has become extremely complicated. Besides, it is in such a situation that there are too many options to find a suitable solution in a tuning operation after having formed the chip.

In Patent Document 1, Unexamined Japanese Patent Application Publication No. 2000-195280, a multi-level storage scheme in a NAND-type flash memory is disclosed.

In Patent Document 2, Unexamined Japanese Patent Application Publication No. 07-302175, there is disclosed such a technology that a NAND-type flash memory is controlled with a firmware stored in an ROM in a memory controller.

### SUMMARY OF THE INVENTION

According to an aspect of the present invention, there is provided a semiconductor memory system including:

a non-volatile semiconductor memory device; and

a memory controller configured to execute operation control of the non-volatile semiconductor memory device, wherein a sequencer contained in control logic for the non-volatile semiconductor memory device is composed of software developed in the memory controller.

According to another aspect of the present invention, there is provided a semiconductor memory system including:

a non-volatile semiconductor memory device having a normal data area for storing multi-level data, a ROM area for storing binary data and an internal control circuit; and

a memory controller configured to execute operation control of the non-volatile semiconductor memory device, wherein

the internal control circuit has hardware control logic used for reading/writing binary data in the ROM area, and

the memory controller has software control logic used for reading/writing multi-level data in the normal data area.

### BRIEF DESCRIPTION OF THE DRAWINGS

FIG. 1 shows a memory system in accordance with an embodiment of the present invention.

FIG. 2 shows the cell array of the non-volatile semiconductor memory device.

FIG. 3 shows the detailed cell array.

FIG. 4 shows the sense unit in the non-volatile semiconductor memory device.

FIG. 5 shows the internal control circuit in the non-volatile semiconductor memory device.

FIG. 6 shows the data areas in the cell array of the non-volatile semiconductor memory device.

FIG. 7 shows the power-on reset operation of the non-volatile semiconductor memory device.

FIG. 8 shows the four-level data threshold distributions and the bit assignment of the non-volatile semiconductor memory device.

FIG. 9 shows the lower page write sequence of the non-volatile semiconductor memory device.

FIG. 10 shows the upper page write sequence of the non-volatile semiconductor memory device.

FIG. 11 shows another embodiment applied to a digital still camera.

FIG. 12 shows the internal configuration of the digital still camera.

FIGS. 13A to 13J show other electric devices to which the embodiment is applied.

### DETAILED DESCRIPTION OF THE EMBODIMENTS

Illustrative embodiments of this invention will be explained with reference to the accompanying drawings below.

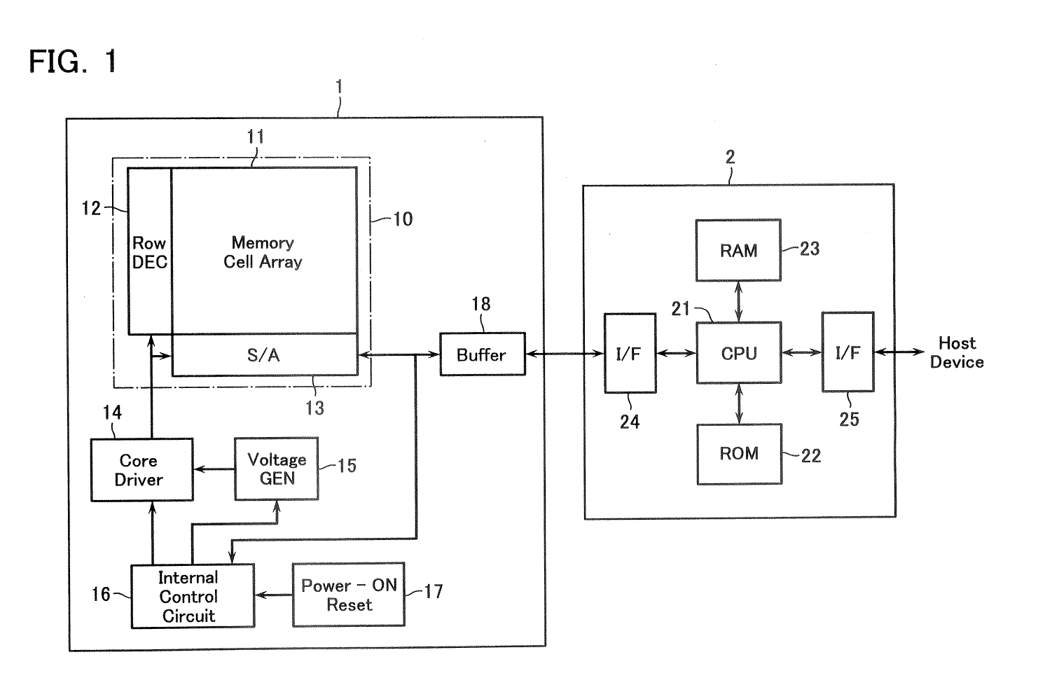

FIG. 1 shows a memory system in accordance with an embodiment, which includes a non-volatile semiconductor memory device 1 and a memory controller 2 for executing operation control thereof. This system is, for example, formed as a memory card, in which the memory device 1 and the memory controller 2 are installed.

In the non-volatile semiconductor memory device 1, cell array 11, row decoder 12 and sense amplifier 13 constitute a memory core 10. Row decoder 12 is selectively driving word lines; and sense amplifier circuit 13 for sensing the bit line data. Disposed to drive the memory core 10 is a core driver 14, and there is prepared a voltage generating circuit 15 for generating various, high and medium voltages required of the core driver 14.

Internal control circuit 16 is prepared for timing control and voltage control of the core drive circuit 14 and voltage generating circuit 15. To detect power-on to perform an initializing operation, power-on reset circuit 17 is prepared. Buffer 18 is prepared for transmitting/receiving write/read data, and command and address data between the non-volatile semiconductor memory 1 and memory controller 2.

Memory controller 2 has CPU 21, ROM 22 for storing control program, and RAM 23 for functioning as an operation area of CPU 21, in which software control logic is developed. Further disposed in the memory controller 2 are interfaces 24 and 25 serving for transmitting/receiving data of memory device 1 and a host device (not shown), respectively.

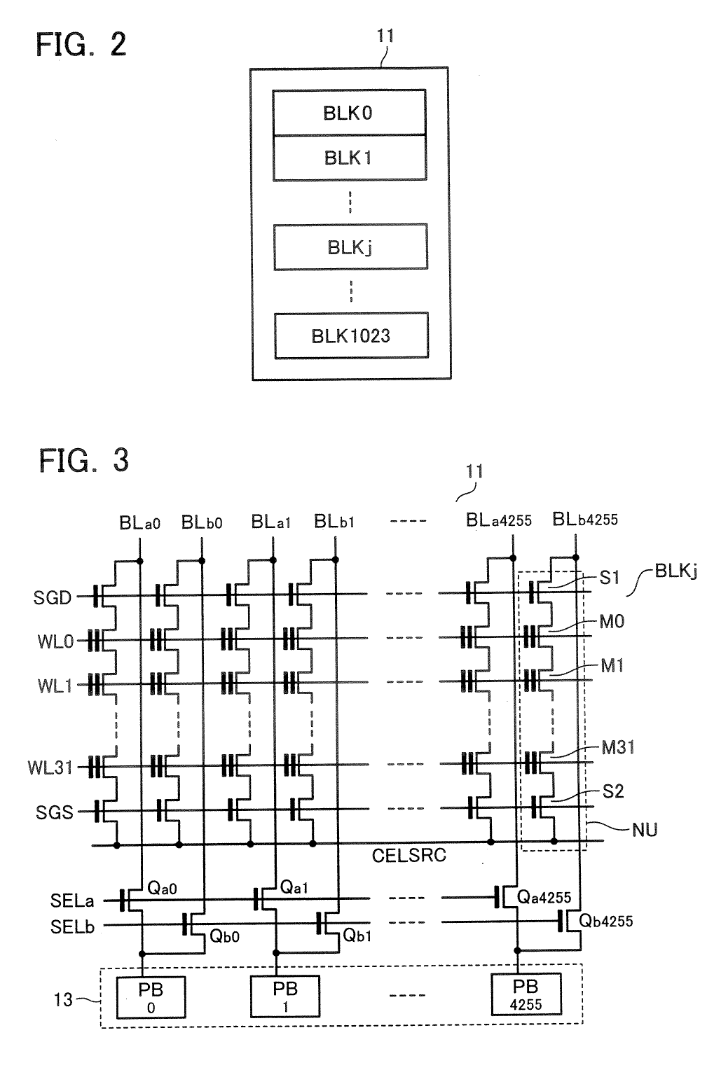

FIGS. 2 and 3 show a detailed configuration of the memory cell array 11. This cell array 11 is NAND-type one, in which NAND cell units (i.e., NAND strings) NU are arranged. Each NAND cell unit NU contains a plurality of electrically rewritable and non-volatile memory cells (thirty two cells in this case) M0-M31 connected in series.

One end of the NAND cell unit NU is coupled to bit line BLax or BLbx (for example, x=0˜4225) via select gate transistor S1; and the other end thereof to common source line CERSRC via another select gate transistor S2.

Control gates of the corresponding memory cells in the respective NAND cell units are coupled in common to word lines WL0-WL31, respectively, while gates of the select gate transistors S1 and S2 are coupled to select gate lines SGD and SGS, respectively.

A set of NAND cell units sharing word lines constitutes a block BLKj, which serves as an erase unit. As shown in FIG. 2, multiple blocks BLK0, BLK1, . . . , BLK1023 are arranged in the bit line direction in the cell array 11.

Even numbered bit line BLax and odd numbered bit line BLbx share a sense unit PBx in the sense amplifier circuit 13. That is, even numbered bit line BLax and odd numbered bit line BLbx are selectively coupled to the sense unit PBx via select transistors Qax and Qbx, which are driven with select signals SELa and SELb, respectively.

A set of memory cells selected by all even numbered bit lines and a word line constitutes a first sector, while another set of memory cells selected by all odd numbered bit lines and a word line constitutes a second sector, and one sector serves as a unit, all cells in which are subjected to simultaneous data read or write.

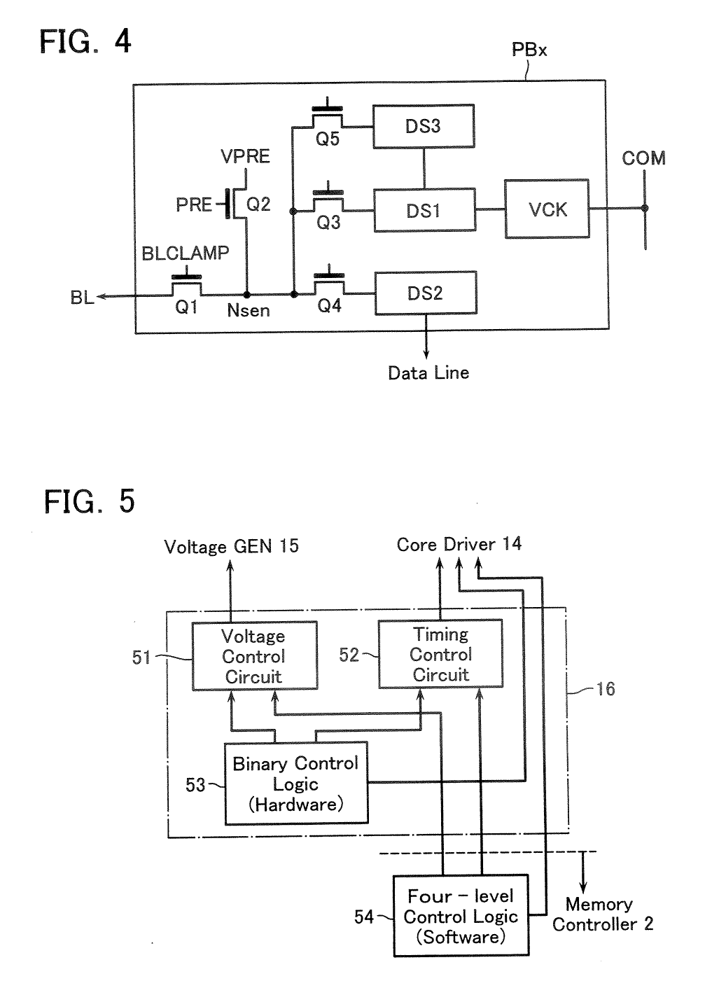

FIG. 4 shows an example of the sense unit PBx. Supposing that a four-level data storage scheme is used in this embodiment, three data storage parts DS1-DS3 are prepared in the sense unit PBx. Data storage part DS1 is a main data latch for holding read data or write data.

Data storage part DS2 is a data latch serving as a cache for transmitting/receiving data between the external and itself. Further, data storage part DS2 is used for holding the lower page data in the four-level data, which has already been written in the cell array, for referring to it for the purpose of doing write-verify of the upper page data.

Data storage part DS3 is used for temporarily holding write data loaded in data storage part DS2 for serving for setting write data used in the following cycle. The situation will be explained below. Data write is basically performed by a sector in such a manner that “0” write is defined as an operation for boosting cell's threshold voltage while “1” write (i.e., write inhibit) is defined as an operation for keeping cell's threshold voltage as it is. Write-verify is performed for each cell, and controlled as follows: when “0” write has been verified for a cell, it will be set at the “1” write mode hereinafter. Data storage part DS3 is used for such write data controlling as described above.

These data storage parts DS1, DS2 and DS3 are coupled to sense node Nsen via transfer gate transistors Q3, Q4 and Q5, respectively. The sense node Nsen is coupled to a selected bit line via a clamping transistor Q1. Further coupled to the sense node Nsen is a precharge transistor Q2, which serves for precharging the bit line and the sense node Nsen.

At a data write time, it designates one page write completion that data storage parts DS1 in one page sense units become all “1” at a write-verify step. To detect the write completion, verify-check circuit VCK is prepared, which is coupled to judging signal line COM shared by all sense units. The internal control circuit 16 or memory controller 2 monitors this judging signal line COM, thereby being able to judge the write completion.

This embodiment has a feature that a main logic function of operation controlling the non-volatile semiconductor memory device 1, i.e., a sequencer for achieving the control sequence, is not formed as a hardware sequencer in the internal control circuit 16, but stored as a software sequencer in the memory controller 2. Explaining in detail, the software data for achieving the sequencer is stored in ROM 22 in the memory controller 2, and it will be read out and developed in RAM 23. Alternatively, more preferably, the software control logic data is stored in the cell array 11 in the memory device 1, and it will be read out at a power-on time, and transferred to the memory controller 2, thereby being developed in RAM 23.

The latter case will be explained in detail below.

FIG. 5 shows the configuration of the internal control circuit 16 in the non-volatile semiconductor memory device 1. The control circuit 16 includes voltage control circuit 51 for controlling the voltage generating circuit 15, timing control circuit 52 for controlling the core drive circuit 14 and binary control logic (hardware) 53, which controls voltage control circuit 51, timing control circuit 52 and core drive circuit 14 to read out four-level control logic data (i.e., sequencer function data) stored in the cell array 11 as binary data.

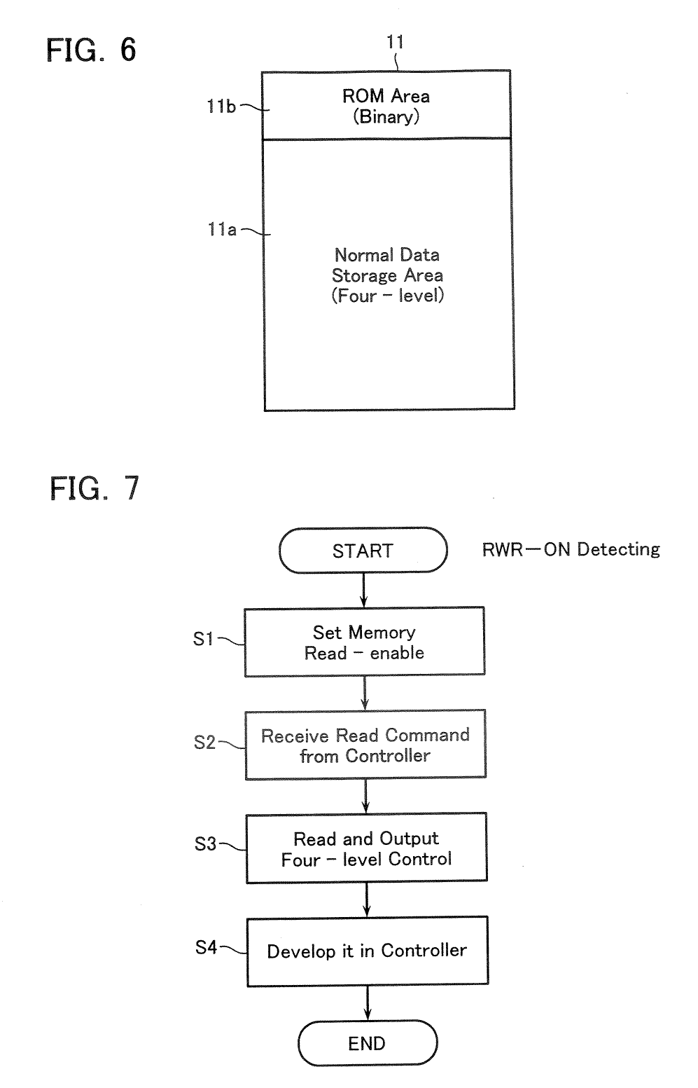

In other words, the cell array 11 has, as shown in FIG. 6, normal data area 11a serving as a normal four-level data area and ROM area 11b, which stores the four-level control logic data as binary data. The four-level control logic data serves as the sequencer, which is used for reading/writing/erasing the four-level data stored in the normal data area 11a.

The binary control logic 53 in the control circuit 16 automatically reads out the four-level control logic data in the ROM area 11b of the cell array 11 under the control of the power-on reset circuit 17 at a power-on time, and transfers it to memory controller 2.

Therefore, as shown in FIG. 5, four-level control logic 54 is not stored in the internal control circuit 16, but stored in the memory controller 2 as software. In accordance with the for-level control logic 54, sequence controls such as four-level data writing into the cell array 11 will be executed.

FIG. 7 shows the above-described power-on reset operation flow. Detecting power-on, the power-on reset circuit 17 sets the non-volatile semiconductor memory device 1 to be in a read-enable state (step S1). For example, the non-volatile semiconductor memory device 1 outputs a READY state signal.

In response to the READY state signal, memory controller 2 will issue a read command. The non-volatile semiconductor memory device 1 receiving it (step S2), internal control circuit 16 automatically reads out the control logic data stored on the ROM area 11b, and transfers it to the memory controller 2 (step S3). The four-level control logic data transferred to the memory controller 2 is developed on RAM 23 (step S4), and adapted to four-level data read/write of the non-volatile semiconductor memory device hereinafter.

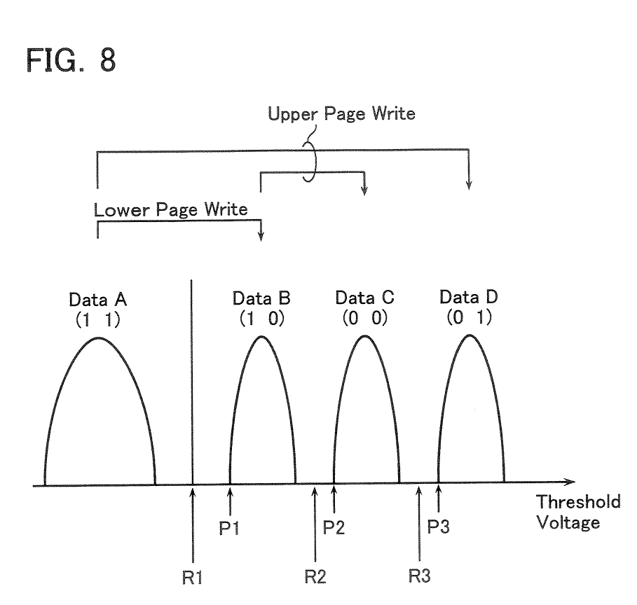

Four-level data stored in the normal data area 11a is, for example, set in one of data states “A”, “B”, “C” and “D”, which are defined by the threshold voltage distributions as shown in FIG. 8. Four-level data being expressed as (x,y), where x, y are the upper and lower page data, respectively, these page data are assigned to the four data states of “A”, “B”, “C” and “D” as follows: A=(1,1), B=(1,0), C=(0,0) and D=(0,1).

Data state “A” is, for example, an erase state with a negative threshold voltage, which is set in a collective erase operation performed by a block. To selectively boost cell's threshold voltage from data “A” to data “B”, that is the lower page write. To selectively write data “C” and “D” into data “A” and “B” cells, respectively, that is the upper page write.

To define the lowest values P1, P2 and P3 of the threshold voltage distributions of data states “B”, “C” and “D”, respectively, verify voltages are applied to the selected word line at a write-verify time. Read voltages R1, R2 and R3 used at a normal read time are set between the data threshold distributions.

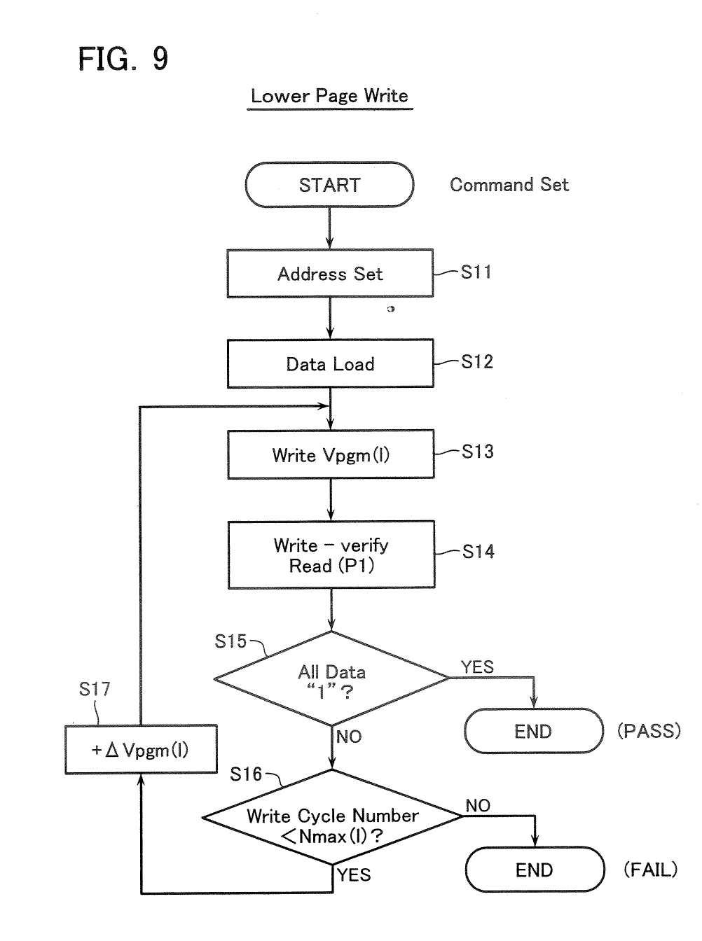

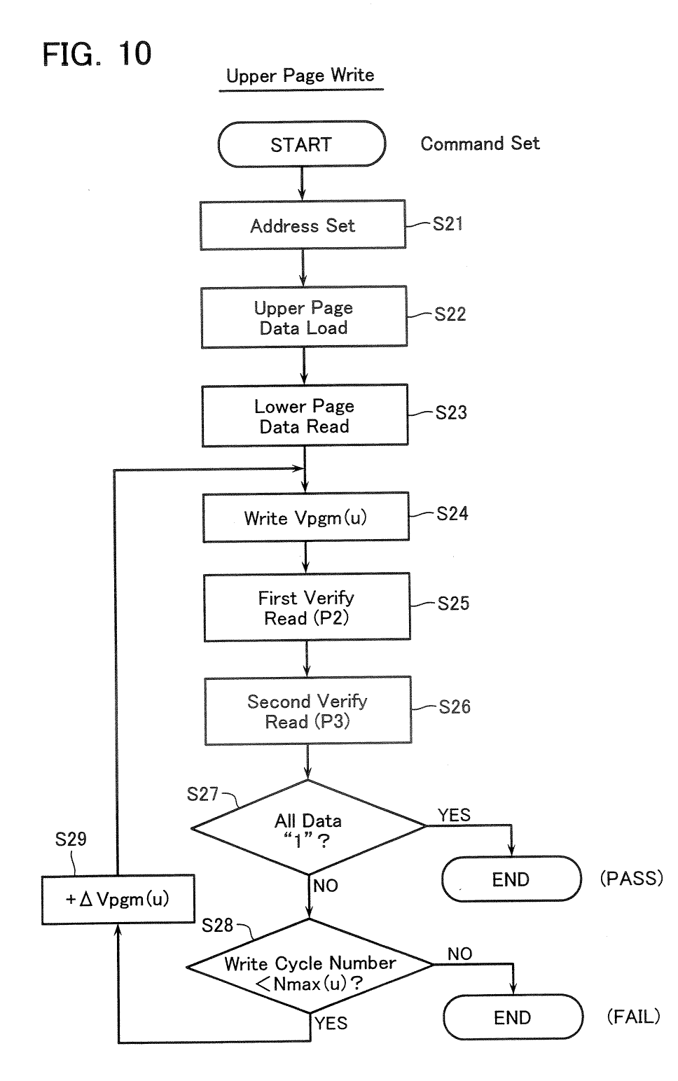

FIGS. 9 and 10 show the lower page and upper page write sequences, respectively, with respect to the above-described four-level data scheme.

The host device issuing write command, the lower page write sequence starts. Address setting (step S11) and write data (the lower page data) loading (step S12) into the non-volatile semiconductor memory device 1 are followed the command input via the memory controller 2, write (write voltage application) (step S13) and write-verify (step S14) are performed.

Write voltage Δpgm(l) is initially set at Vpgm0(l), and stepped-up by ΔVpgm(l) at the following cycles. At the lower page write time, write-verify read is performed, as shown in FIG. 8, with the verify voltage P1.

After the write-verify, it is judged whether the data storage parts DS1 in the sense amplifier have become in the all “1” state or not, i.e., write completion judgment is performed (step S15). The judged result being “YES”, the write sequence will be normally ended. If “NO”, and if it is judged that the number of write cycles has not reached Nmax(l) (step S16), write voltage Vpgm(l) is stepped-up by ΔVpgm(l) (step S17), and write voltage application is performed again (step S13). In case the number of write cycles has reached Nmax(l), the write sequence ends as this write is “FAIL”.

The upper page write sequence also starts when the host device issues write command. Address setting (step S21) and write data (the upper page data) loading (step S22) into the non-volatile semiconductor memory device 1 are followed the command input via the memory controller 2. Subsequently, the lower page data, which have already been written, are read out (step S23), and write (write voltage application) (step S24) and write-verify steps (S25 and S26) are performed.

Write voltage Vpgm(u) is initially set at Vpgm0(u), and stepped-up by ΔVpgm(u) at the following cycles. Write-verify read is performed in such a manner that at the first verify step S25, verify voltage P2 is used for verifying the data state “C”; and at the second verify step S26, verify voltage P3 is used for verifying the data state “D”.

As described above, verify voltage P2 is used at the first verify step S25. At this time, it is in need of excluding the write data bits of data “D” from the verify object. For this purpose, data processing is performed in the sense amplifier so that data bits for writing data “D” are excluded from the verify object with reference to the lower page data read out from the cell array and stored in data storage part DS2. The detailed explanation will be omitted here.

After the write-verify with two steps, it is judged whether the data storage parts DS1 in the sense amplifier have become in the all “1” state or not, i.e., write completion judgment is performed (step S27). The judged result being “YES”, the write sequence will be normally ended. If “NO”, and if it is judged that the number of write cycles has not reached Nmax(u) (step S28), write voltage Vpgm(u) is stepped-up by a Vpgm(u) (step S29), and write voltage application is performed again (step S24). In case the number of write cycles has reached Nmax(u), the write sequence ends as “FAIL”.

In this embodiment, the sequencer for achieving the write sequence explained with reference to FIGS. 9 and 10 is not formed as hardware one in the memory device 1, but held as software one in the memory controller 2. In detail, the software control logic data is written in the ROM area in the non-volatile semiconductor memory device 1 and read out to be developed in the memory controller 2 as a power-on reset operation.

In the write sequence function, there are not only the basic write control flow shown in FIGS. 9 and 10 but also various parameter data used at every step (for example, voltage trimming data, timing trimming data and so on). Enumerating the above-described parameter data in detail, there are voltage values of the write voltages Vpgm(1), Vpgm(u), pulse widths, pulse application timings, step-up voltages ΔVpgm(l), ΔVpgm(u) of the write voltages, verify voltages P1, P2 and P3, write cycles Nmax(l), Nmax(u) and the like. These parameter data also are written in the ROM area 11b in the non-volatile semiconductor memory device 1 and read out to be developed in the memory controller 2 during the power-on reset operation.

Although the detailed explanation is omitted, it is possible to make the memory controller 2 store not only the write sequence logic for four-level data storage area but also read and/or erase control logic as software data.

According to this embodiment, the hardware control logic in the non-volatile semiconductor memory device is made simple. This fact has a material meaning when the non-volatile semiconductor memory device is increased in capacity in accordance with microfabrication technologies or multi-level technologies. Particularly, in case the control logic of the non-volatile semiconductor memory device is made complicated, it becomes difficult to understand the suitable solution of the control logic of the non-volatile semiconductor memory device at a design stage of it.

Therefore, it will be in such a situation as: it is not found till the chip is made operated after having finished the non-volatile semiconductor memory chip fabrication that the control logic is not suitable. Explaining in other words, in such a conventional scheme that the control logic is composed of a hardware logic circuit such as PLA (Programmable Logic Array), the reliability and throughput of the non-volatile semiconductor memory device of a new generation will be reduced. Further, to secure high reliability and high throughput, it is necessary to change the design and re-fabricate the chip.

By contrast, in this embodiment, the main part of the control logic of the non-volatile semiconductor memory device is held in the memory controller as software data. Therefore, even if it is found that the control logic is defective, it may be easily revised by making the software change, and there is no need of changing the design and re-fabricating the chip.

As another embodiment, an electric card using the non-volatile semiconductor memory devices according to the above-described embodiment of the present invention and an electric device using the card will be described bellow.

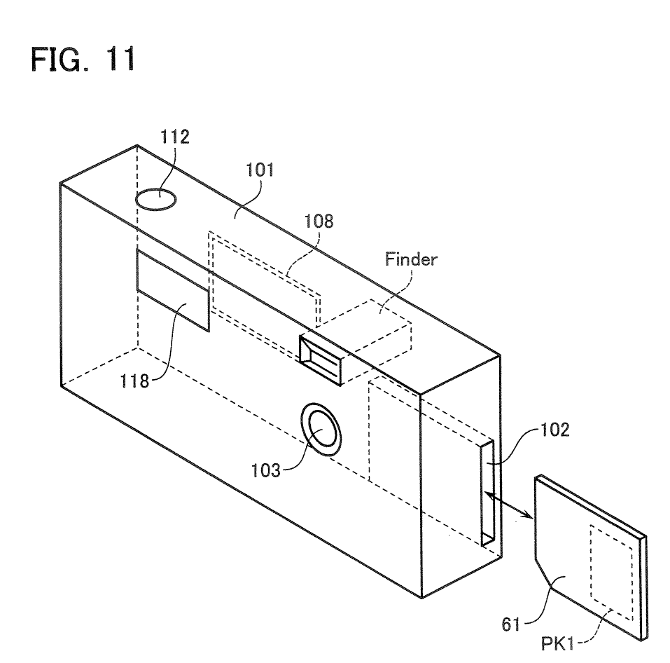

FIG. 11 shows an electric card according to this embodiment and an arrangement of an electric device using this card. This electric device is a digital still camera 101 as an example of portable electric devices. The electric card is a memory card 61 used as a recording medium of the digital still camera 101. The memory card 61 incorporates the semiconductor memory system PK1 in accordance with the above-described embodiment, in which the non-volatile semiconductor memory device and the memory controller integrated or encapsulated.

The case of the digital still camera 101 accommodates a card slot 102 and a circuit board (not shown) connected to this card slot 102. The memory card 61 is detachably inserted in the card slot 102 of the digital still camera 101. When inserted in the slot 102, the memory card 61 is electrically connected to electric circuits of the circuit board.

If this electric card is a non-contact type IC card, it is electrically connected to the electric circuits on the circuit board by radio signals when inserted in or approached to the card slot 102.

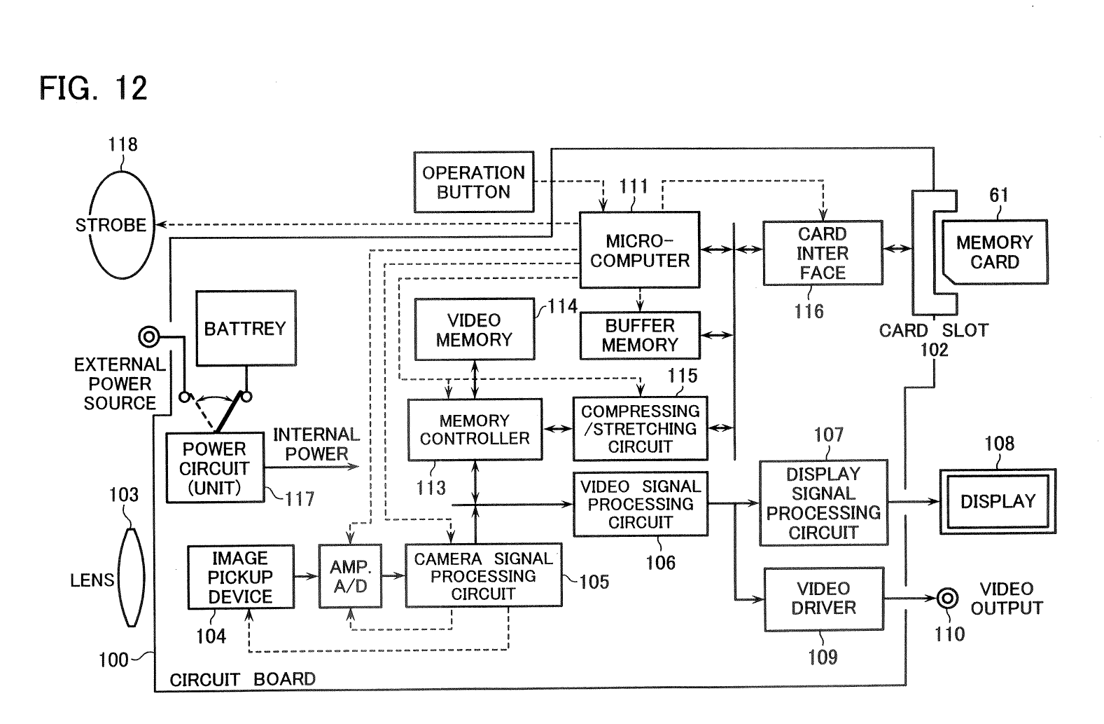

FIG. 12 shows a basic arrangement of the digital still camera. Light from an object is converged by a lens 103 and input to an image pickup device 104. The image pickup device 104 is, for example, a CMOS sensor and photoelectrically converts the input light to output, for example, an analog signal. This analog signal is amplified by an analog amplifier (AMP), and converted into a digital signal by an A/D converter (A/D). The converted signal is input to a camera signal processing circuit 105 where the signal is subjected to automatic exposure control (AE), automatic white balance control (AWB), color separation, and the like, and converted into a luminance signal and color difference signals.

To monitor the image, the output signal from the camera processing circuit 105 is input to a video signal processing circuit 106 and converted into a video signal. The system of the video signal is, e.g., NTSC (National Television System Committee). The video signal is input to a display 108 attached to the digital still camera 101 via a display signal processing circuit 107. The display 108 is, e.g., a liquid crystal monitor.

The video signal is supplied to a video output terminal 110 via a video driver 109. An image picked up by the digital still camera 101 can be output to an image apparatus such as a television set via the video output terminal 110. This allows the pickup image to be displayed on an image apparatus other than the display 108. A microcomputer 111 controls the image pickup device 104, analog amplifier (AMP), A/D converter (A/D), and camera signal processing circuit 105. To capture an image, an operator presses an operation button such as a shutter button 112. In response to this, the microcomputer 111 controls a memory controller 113 to write the output signal from the camera signal processing circuit 105 into a video memory 114 as a flame image. The flame image written in the video memory 114 is compressed on the basis of a predetermined compression format by a compressing/stretching circuit 115. The compressed image is recorded, via a card interface 116, on the memory card 61 inserted in the card slot.

To reproduce a recorded image, an image recorded on the memory card 61 is read out via the card interface 116, stretched by the compressing/stretching circuit 115, and written into the video memory 114. The written image is input to the video signal processing circuit 106 and displayed on the display 108 or another image apparatus in the same manner as when image is monitored.

In this arrangement, mounted on the circuit board 100 are the card slot 102, image pickup device 104, analog amplifier (AMP), A/D converter (A/D), camera signal processing circuit 105, video signal processing circuit 106, display signal processing circuit 107, video driver 109, microcomputer 111, memory controller 113, video memory 114, compressing/stretching circuit 115, and card interface 116.

The card slot 102 need not be mounted on the circuit board 100, and can also be connected to the circuit board 100 by a connector cable or the like.

A power circuit 117 is also mounted on the circuit board 100. The power circuit 117 receives power from an external power source or battery and generates an internal power source voltage used inside the digital still camera 101. For example, a DC-DC converter can be used as the power circuit 117. The internal power source voltage is supplied to the respective circuits described above, and to a strobe 118 and the display 108.

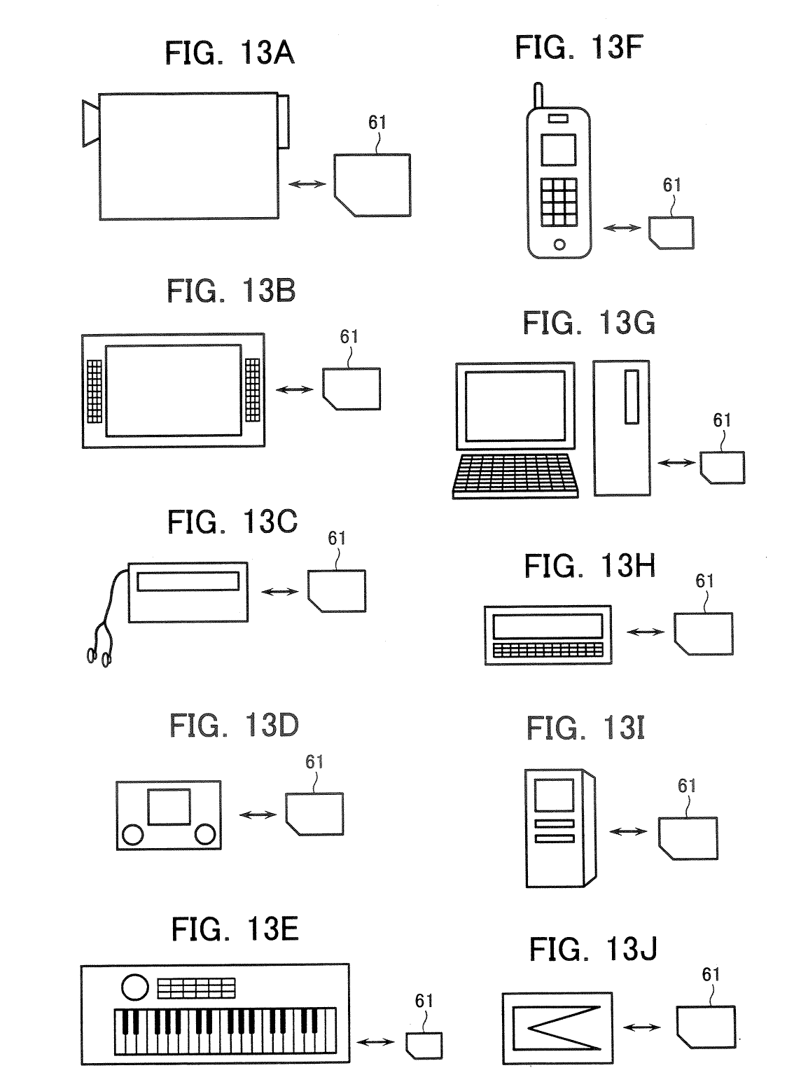

As described above, the electric card according to this embodiment can be used in portable electric devices such as the digital still camera explained above. However, the electric card can also be used in various apparatus such as shown in FIGS. 13A to 13J, as well as in portable electric devices. That is, the electric card can also be used in a video camera shown in FIG. 13A, a television set shown in FIG. 13B, an audio apparatus shown in FIG. 13C, a game apparatus shown in FIG. 13D, an electric musical instrument shown in FIG. 13E, a cell phone shown in FIG. 13F, a personal computer shown in FIG. 13G, a personal digital assistant (PDA) shown in FIG. 13H, a voice recorder shown in FIG. 13I, and a PC card shown in FIG. 13J.

This invention is not limited to the above-described embodiments. It will be understood by those skilled in the art that various changes in form and detail may be made without departing from the spirit, scope, and teaching of the invention.

What is claimed is:

1. A semiconductor memory system comprising:
a non-volatile semiconductor memory device; and
a memory controller configured to execute operation control of the non-volatile semiconductor memory device, wherein
a sequencer contained in control logic for the non-volatile semiconductor memory device is composed of software developed in the memory controller.

2. The semiconductor memory system according to claim 1, wherein
the non-volatile semiconductor memory device comprises: a cell array, in which a ROM area is included, the control logic data used for composing the sequencer being stored in the ROM area; and an internal control circuit, and wherein
the control logic data in the ROM area is automatically read out and transferred to the memory controller at a power-on time under the control of the internal control circuit.

3. The semiconductor memory system according to claim 2, wherein
the cell array has a plurality of NAND cell units arranged therein, each NAND cell unit including a plurality of memory cells connected in series.

4. The semiconductor memory system according to claim 2, wherein
the cell array has a normal data area, which is operation-controlled with the memory controller, to store multi-level data, and
the ROM area stores the control logic data as binary data.

5. The semiconductor memory system according to claim 4, wherein
parameter data attached to the sequencer are stored in the ROM area as binary data and automatically read out to be transferred to the memory controller at the power-on time under the control of the internal control circuit together with the control logic data constituting the sequencer.

6. The semiconductor memory system according to claim 1, wherein
the non-volatile semiconductor memory device comprises:
a cell array having a normal data area for storing multi-level data and a ROM area for storing multi-level control logic data as binary data used for constituting the sequencer, the cell array including NAND cell units, in which a plurality of memory cells are connected in series;
an internal control circuit configured to perform read/write of the cell array; and
a power-on reset circuit configured to detect power-on and make the internal control circuit automatically read data in the ROM area and output it.

7. The semiconductor memory system according to claim 1, wherein
the memory system is a memory card.

8. A semiconductor memory system comprising:
a non-volatile semiconductor memory device having a normal data area for storing multi-level data, a ROM area for storing binary data and an internal control circuit; and
a memory controller configured to execute operation control of the non-volatile semiconductor memory device, wherein
the internal control circuit has hardware control logic used for reading/writing binary data in the ROM area, and
the memory controller has software control logic used for reading/writing multi-level data in the normal data area.

9. The semiconductor memory system according to claim 8, wherein
the binary data in the ROM area is automatically read out and transferred to the memory controller at a power-on time under the control of the internal control circuit, thereby constituting the software control logic.

10. The semiconductor memory system according to claim 8, wherein
the non-volatile semiconductor memory device has a cell array with NAND cell units arranged therein, each NAND cell unit including a plurality of memory cells connected in series.

11. The semiconductor memory system according to claim 9, wherein
the ROM area stores parameter data attached to the software control logic data, and
the parameter data is automatically read out and transferred to the memory controller at the power-on time together with the software logic data under the control of the internal control circuit.

12. The semiconductor memory system according to claim 8, wherein
the internal control circuit includes a voltage control circuit and a timing control circuit, which are used at reading/writing times with the hardware control logic and the software control logic.

13. The semiconductor memory system according to claim 8, wherein
the non-volatile semiconductor memory device comprises:
a cell array including the normal data area and the ROM area defined therein, the cell array having NAND cell units, in which a plurality of memory cells are connected in series; and
a power-on reset circuit configured to detect power-on and make the internal control circuit automatically read data in the ROM area and output it.

14. The semiconductor memory system according to claim 8, wherein
the memory system is a memory card.
